(19) United States
(12) Patent Application Publication
(10) Pub. No.: US 2025/0316437 A1
(43) Pub. Date: Oct. 9, 2025

(54) ULTRA-HIGH SENSITIVITY HYBRID INSPECTION WITH FULL WAFER COVERAGE CAPABILITY

(71) Applicant: KLA Corporation, Milpitas, CA (US)

(72) Inventors: Alan Brodie, Palo Alto, CA (US); Lawrence Muray, Moraga, CA (US); John Gerling, Livermore, CA (US); James Spallas, San Ramon, CA (US)

(73) Assignee: KLA Corporation, Milpitas, CA (US)

(21) Appl. No.: 18/909,820

(22) Filed: Oct. 8, 2024

Related U.S. Application Data
(60) Provisional application No. 63/574,923, filed on Apr. 5, 2024.

(51) Int. Cl. H01J 37/07; H01J 37/09; H01J 37/14; H01J 37/20; H01J 37/28

(52) U.S. Cl. CPC H01J 37/07; H01J 37/09; H01J 37/14; H01J 37/20; H01J 37/28; H01J 2237/2817

(57) ABSTRACT

A device includes a two dimensional array of probes for inspecting a wafer. The two dimensional array includes at least one electron beam column or a magnetic element located in each dimension of the two dimensional array. Each electron beam column includes: an electron source, and a detector in line with the electron source. The two dimensional array is arranged such that each electron beam column is located adjacent to a magnetic element to minimize optical variation resulting from one or more magnetic fields.

### CROSS REFERENCE TO RELATED APPLICATIONS

Pursuant to 35 U.S.C. § 119 (e), this application is entitled to and claims the benefit of the filing date of U.S. Provisional App. No. 63/574,923 filed Apr. 5, 2024, entitled “Improved Ultra-High Sensitivity Hybrid Inspection With Full Wafer Coverage Capability”, the content of which is incorporated herein by reference in its entirety for all purposes.

### TECHNICAL FIELD

The disclosure generally relates to the field of wafer inspection systems. More particularly the present disclosure relates to defect detection using a ultra-high sensitivity hybrid inspection system.

### BACKGROUND

Generally, the industry of semiconductor manufacturing involves highly complex techniques for fabricating integrated circuits using semiconductor materials which are layered and patterned onto a substrate, such as silicon. Due to the large scale of circuit integration and the decreasing size of semiconductor devices, the fabricated devices have become increasingly sensitive to defects. That is, defects which cause faults in the device are becoming increasingly smaller. The device needs to be generally fault free prior to shipment to the end users or customers.

Defect detection is generally implemented across a full wafer for yield management in the semiconductor manufacturing industry. Types of defects, counts of defects, and signatures found by inspection systems (or inspectors) provide valuable information for semiconductor fabrication to ensure that the manufacturing process established in the research and development phase can ramp, that the process window confirmed in the ramp phrase can be transferrable to high volume manufacturing (HVM), and that day-to-day operations in HVM are stable and under-control.

An optical inspector is currently the only viable platform in the market to deliver enough speed to economically yield full wafer inspection. Full wafer coverage with an optical inspector has been implemented for HVM due to low expected defect counts on the wafer. In a mature process, the expected defect counts are typically less than 1000. Because of these low counts, combined with the mostly random locations of the defects across a 300 mm wafer, full wafer coverage with an optical inspector has been historically used to monitor the HVM process.

As design rules shrink, however, the sensitivity gap between what is required for defect monitoring and what can be provided by optical inspector widens. This sensitivity gap is caused by the increasing disparity between critical dimension (CD) length and optical point spread function (PSF) size. The ratio between CD and optical PSF (CD:PSF) for a current design node is less than 1:10, and the CD:PSF ratio will continue to increase for subsequent generation design nodes. Because the CD:PSF ratio today is already 1:10, a single PSF can cover several design or defect structures. As a result, one generated optical signal can come from a single source (such as DOI) inside the PSF or multiple sources (such as a combination of DOI and wafer noise artifacts or just several wafer noise artifacts) inside the PSF. This effect causes ambiguity for defect detection. For example, a similar optical signal can be generated from a bridge type defect or different types of pattern edge placement error nuisances due to a large CD:PSF ratio. This effect creates ambiguity about how the optical signal is generated. As a result, an optical inspector is not able to differentiate certain defect signals from nuisance signals, which reduces optical inspector's ability to cleanly detect DOI's. Thus, current inspection systems and methodologies have a high sensitivity defect detection performance gap.

Accordingly, there is a continued demand for improved semiconductor wafer inspector systems and techniques.

### BRIEF DESCRIPTION OF THE DRAWINGS

FIG. 1 illustrates an array of high-resolution probes having a fixed position and a wafer that is moved under such high-resolution probe, in accordance with embodiments of the present disclosure.

FIG. 2 illustrates an example high-resolution, distributed inspection tool, in accordance with embodiments of the present disclosure.

FIGS. 3A-3B illustrate a two dimensional array of high-resolution probes, in accordance with embodiments of the present disclosure.

FIGS. 4A-4D illustrate different two dimensional configuration patterns, in accordance with embodiments of the present disclosure.

FIG. 5 illustrates examples of fields surrounding lenses in a particular arrangement, in accordance with embodiments of the present disclosure.

FIGS. 6A-6D illustrate different configurations of different types of shielding, in accordance with embodiments of the present disclosure.

FIG. 7 illustrates an example hybrid magnetic-electrostatic column configuration, in accordance with embodiments of the present disclosure.

### DETAILED DESCRIPTION OF EXAMPLE EMBODIMENTS

In the following description, numerous specific details are set forth in order to provide a thorough understanding of the present disclosure. The present disclosure may be practiced without some or all of these specific details. In other instances, well known process operations have not been described in detail to not unnecessarily obscure the present disclosure. While the disclosure will be described in conjunction with the specific embodiments, it will be understood that it is not intended to limit the disclosure to the embodiments.

As mentioned above, there is a need for improved semiconductor wafer inspector systems and techniques. Large CD:PSF ratios can result in signals of small defects that are always embedded in the tail end of a background distribution signal function for an optical inspector. Small defect signals can be confused with the tail end of the noise distributions. For example, if an optical inspection threshold is set low, a high number of nuisance signals, along with actual defect signals, are flagged as candidate defects. As semiconductor devices have increasingly reduced CD, the degree of confusion between DOI and nuisance signals becomes worse. This confusion leads to an inability for optical inspector to detect small defects with acceptable nuisance rates.

High-resolution scanning systems, such as an electron beam inspector (EBI), can be a next best solution for resolving this optical sensitivity gap. However, high-resolution scanning systems are not feasible for inspection in a high-volume manufacturing process because of inadequate wafer throughput. For example, although the resolution of EBI is high enough to resolve small semiconductor structures, EBI cannot currently deliver throughput that is acceptable for semiconductor manufacturing yield monitoring. The adoption of these high-resolution systems, such as EBI, are limited to the research and development phase due to insufficient throughput. Since high-resolution systems typically cannot provide full wafer scans, they present challenges for adoption into HVM (high volume manufacturing) inspection.

In certain embodiments of the present invention, the sensitivity defect detection performance gap is solved with a hybrid optical and a distributed high-resolution inspector system. Together the combined system changes the inspection paradigm. In general, the high-resolution system includes a fast, distributed probe architecture for quickly scanning a high number of potential defect sites. Thus, the hybrid inspector system leverages the strengths of both an optical inspector and a distributed, high-resolution system. For example, such hybrid inspector can provide detection of current design node 5 nm defects within 2 hours with full wafer coverage. Additionally, the hybrid inspector can handle a defect distribution that is random or systematic.

An aggressive threshold may be set for the optical inspector to enable at least a 5 nm defect sensitivity so that DOI's (defects of interest) can be detected in the optical scans. An aggressive threshold for the optical inspector is selected to likely result in 5-20 million candidate defect and nuisance sites from the 1st phrase of inspection. Locations for these sites can then be sent to a high-resolution inspector for DOI/nuisance separation. To enable full wafer inspection coverage in less than 2 hours, this high-resolution inspector is operable to visit 5-20 million randomly occurring sites and perform DOI/nuisance separation in 1 hour or less. The specified site count range may vary based on the fabrication process and device design parameters. In other words, the hybrid inspection system contains (1) an optical inspector that generates enough site signals for 5 nm defect detection and has the capability to scan a full wafer in less than 1 hour and (2) a high-resolution, fast inspector that has the capability to visit 5-20 million sites randomly distributed across the wafer in less than 1 hour and perform defect detection for each site visited. Inspection systems can be configured using a linear array of probes or a two dimensional array of probes. While a linear array is sufficient, as described in U.S. Pat. No. 10,545,099, which is incorporated by reference herein in its entirety, a two dimensional array offers several improvements and advantages, as described below.

Thus, the techniques and mechanisms described herein provide example approaches, as well as example system implementations, the details of where are described below with reference to the following figures.

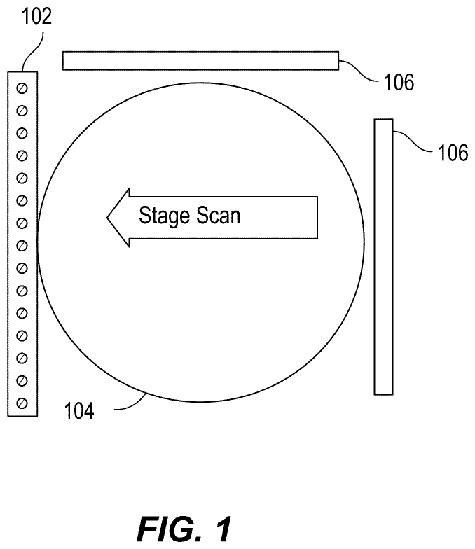

FIG. 1 illustrates a linear array of probes 102 having a fixed position and stage 104 with a wafer thereon that moves under the fixed probes 102 in accordance with embodiments of the present disclosure. In this example, the inspector may also include a pair of interferometers 106 for accurately determining the wafer position with respect to each probe. More laser interferometers may be used as needed. The interferometers are positioned along both the X and Y axis of the stage to track both directions. Additional laser interferometers may be used to track the location of the probes. This could be a minimum of two (X&Y) up to a maximum of one per probe. Z-height mapping may also be implemented using a static height map or dynamically with a sensor positioned at each probe. For example, the z-height sensor may be optical in order enable height mapping of any surface. The depth of focus of a single probe alone may not be sufficient to compensate for the variations in the sample height.

This embodiment also includes a relatively large chamber to accommodate the stage movement for moving the wafer back and forth under the probes. Additionally, the stage scans back and forth across the wafer so that this arrangement is associated with a turnaround time and vibrations caused by de-accelerations and accelerations.

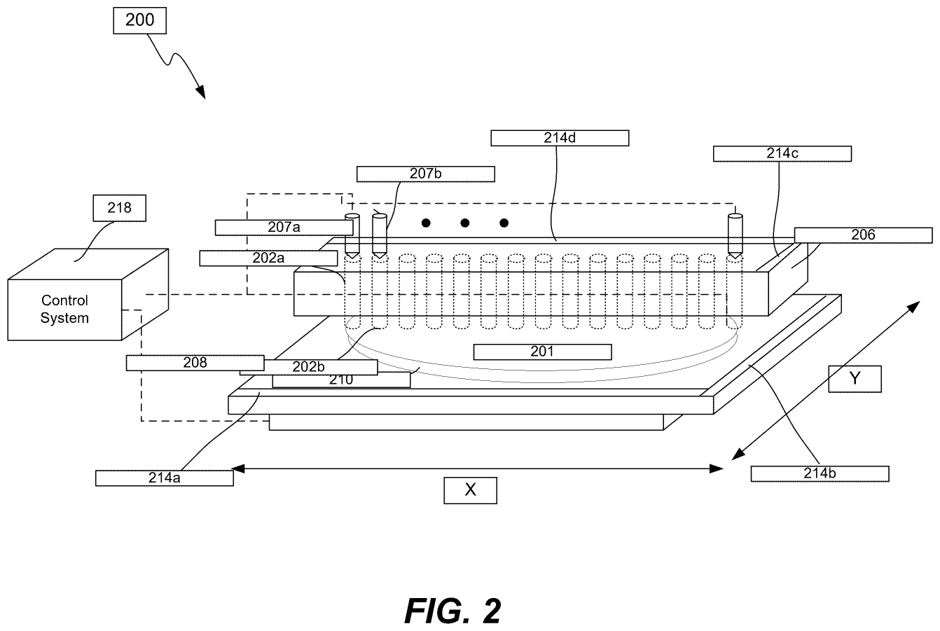

FIG. 2 illustrates an example high-resolution, distributed inspection tool that may be implemented for separating potential defect and nuisance sites in a 1st stage. Referring generally to FIG. 2, a distributed high-resolution system 200 suitable for focusing charged-particles in multiple probes is described in accordance with a specific implementation of the present disclosure. In one example, the system 200 includes a plurality of probes (e.g., 202a and 202b) arranged in a linear array support 206. A plurality of charged particle sources (e.g., 207a and 207b) may be arranged to generate and direct a charged particle beams towards each of the probes with each directing its corresponding charged particle beam towards the sample (e.g., wafer 201). Alternatively, each source may be integrated with each probe. Each charged particle source may include any source known in the art, such as an electron gun.

Each probe or column may include any number of lens(es) and components for focusing its corresponding beam, emitted by its respective charged particle source, a deflector that scans its beam across a defect area of the wafer sample, and a detector that detects emissions from the wafer sample in response to the impinging charged particle beam and forms a high-resolution image. In one aspect, each column in the lens array is a miniature Silicon-Stack-based column (see U.S. Pat. No. 7,045,794, which is incorporated by reference in its entirety).

In some embodiments, each column may further include a set of electron-optic elements. The set of electron-optics may include any electron-optic elements known in the art suitable for focusing and/or directing the electron beam onto a selected portion of the sample 201. In one embodiment, the set of electron-optics elements includes one or more electron-optic lenses. For example, the electron-optic lenses may include, but are not limited to, one or more condenser lenses for collecting electrons from the electron beam source. By way of another example, the electron-optic lenses may include, but are not limited to, one or more objective lenses for focusing the corresponding electron beam onto a selected region of the sample 201. In some embodiments, each electron beam may be directed to the sample 201 at a controlled angle. Because the provided wafer system coordinates does not necessarily coincide with SEM system of coordinates, controlling a fine scan angle may improve matching between the coordinate systems and significantly contribute to sampling performance/accuracy.

In some embodiments, the set of electron-optics elements for each column includes one or more electron beam scanning elements. For example, the one or more electron beam scanning elements may include, but are not limited to, one or more scanning coils or deflectors suitable for controlling a position of the beam relative to the surface of the sample 201. In this regard, the one or more scanning elements may be utilized to scan the electron beam across the sample 201 in a selected scan direction or pattern. For example, the sample 201 may be scanned in tilted or perpendicular bidirectional scans relative to feature placement (e.g., at bidirectional directions and angled with respect to target lines) of certain structures. A controller system 218 may be communicatively coupled to one or more of the electron-optic elements, such as the one or more scanning elements. Accordingly, the controller system 218 may be configured to adjust one or more electron-optic parameters and/or control the scan direction via a control signal transmitted to each set of communicatively coupled electron-optic elements.

In some embodiments, each column may include (or be associated with) a detector assembly for each column that includes an electron collector (e.g., secondary electron collector). The detector assembly may further include an energy filter based, for example, on retarding field principle. In this regard, the energy filter may be configured to stop low energy secondary electrons while passing high energy secondary electrons (i.e., backscattered electrons). If the energy filter is not activated, all secondary electrons are detected according to collection efficiency of the detection system. By subtracting high energy electron image from overall electron image, low energy secondary electron image can be obtained. The detector assembly may further include a detector (e.g., scintillating element and PMT detector) for detecting electrons from the sample surface (e.g., secondary electrons). In some embodiments, the detector of the detector assembly includes a light detector. For example, the anode of a PMT detector of the detector may include a phosphor anode, which is energized by the cascaded electrons of the PMT detector absorbed by the anode and may subsequently emit light. In turn, the light detector may collect light emitted by the phosphor anode in order to image the sample 201. The light detector may include any light detector known in the art, such as, but not limited to, a CCD detector or a CCD-TDI detector. The system 200 may include additional/alternative detector types such as, but not limited to, Everhart-Thornley type detectors. In addition, in some embodiments, system 200 may also include a microchannel plate (MCP) (not shown) or a multi-channel segmented silicon detector (p-i-n diode or an avalanche photo-diode (APD), as described in U.S. Pat. No. 11,699,607, which is incorporated by reference herein).

While the foregoing description is focused on each detector assembly in the context of the collection of secondary electrons, this should not be interpreted as a limitation on the present disclosure. It is recognized herein that each detector assembly may include any device or combination of devices known in the art for imaging or characterizing a sample surface or bulk with a charged particle beam. For example, each detector assembly may include any particle detector known in the art configured to collect backscattered electrons, Auger electrons, transmitted electrons or photons (e.g., x-rays emitted by surface in response to incident electrons).

The wafer sample 201 is supported on a chuck 210, which is coupled with a stage 208. In typical arrangements, the stage has a rotatable chuck upon which the wafer is positioned and affixed. The stage 201, chuck 210, and/or array support 206 in certain embodiments can be configured with a movement mechanism to move in one or more directions, including X, Y, Z, tilt, and rotational directions. Each column may be movable together or independently. These movement mechanisms may take the form of both course and fine grade movement mechanisms that are driven by one or more screw drive and stepper motors, linear drives with feedback position, band actuator and stepper motors, magnetic fields, etc. The movement mechanisms may also implement roller bearings, air bearings, sliding plastic bearings, flexure suspension or magnetic field suspension, etc. In other embodiments, the column system can alternatively or additionally move in one more directions, including X, Y, Z, tilt, and rotational directions. An interferometer mirror may be positioned along each of the movement directions with the stage 208 and/or array support 206 as exemplified with respect to the embodiment of FIG. 1. In FIG. 2, mirrors 214a and 214b are positioned on each X and Y axis of the stage 208, and mirrors 214c and 214d are positioned on each X and Y axis of the array support 208. The mirrors form part of the interferometer system for accurately determining site locations. If either the stage or array does not move, its corresponding mirrors may be removed.

The controller system 218 may be configured for controlling any suitable components of the system 200, as well as receiving and processing high resolutions images acquired by the detectors of the columns. The control system 218 may be communicatively coupled to various components of the system 200. The control system may include one or more processors and electronic components for control, processing, and analysis.

The control system 218 may be configured to adjust one or more charged particle source parameters via a control signal to the each source. For example, the control system 218 may be configured to vary the beam current for an electron beam emitted by each source via a control signal transmitted to control circuitry of the electron beam source.

In some embodiments, the control system 218 is communicatively coupled to the sample stage 208 and/or column assembly. The control system 218 may be configured to adjust one or more stage parameters via a control signal transmitted to the sample stage 208. The control system 218 may be configured to vary the sample scanning speed and/or control the scan direction via a control signal transmitted to control circuitry of the sample stage 208 and/or column assembly. For example, the control system 218 may be configured to vary the speed and/or control the direction with which sample 201 and/or column assembly are linearly translated (e.g., x-direction or y-direction).

In some embodiments, the control system 218 is communicatively coupled to each detector or detector assembly. The control system 218 may be configured to adjust one or more image forming parameters via a control signal transmitted to each detector. For example, the control system 218 may be configured to adjust the extraction voltage or the extraction field strength for the secondary electrons.

Those skilled in the art will appreciate that “the control system 218” may include one or more computing systems or controllers, such as one or more processors configured to execute one or more instruction sets embedded in program instructions stored by at least one non-transitory signal bearing medium.

The control system 218 may be configured to receive and/or acquire data or information (e.g., detected signals/images, statistical results, reference or calibration data, training data, models, extracted features or transformation results, transformed datasets, curve fittings, qualitative and quantitative results, etc.) from other systems by a transmission medium that may include wireline and/or wireless portions. In this manner, the transmission medium may serve as a data link between the control system 218 and other systems (e.g., memory on-board inspector system, external memory, reference inspector source, or other external systems). For example, control system 218 may be configured to receive site locations from the optical inspector from a storage medium (e.g., internal or external memory) via a data link. For instance, results obtained using the inspector 200 system may be stored in a permanent or semi-permanent memory device (e.g., internal or external memory). In this regard, the results may be imported from on-board memory or from an external memory system. Moreover, the control system 218 may send data to other systems via a transmission medium. For instance, qualitative and/or quantitative results, such as metrology values, determined by control system 218 may be communicated and stored in an external memory. In this regard, candidate defect data results may be exported to another system.

Control system 218 may include, but is not limited to, a personal computer system, mainframe computer system, workstation, image computer, parallel processor, or any other device known in the art. In general, the term “computing system” may be broadly defined to encompass any device having one or more processors, which execute instructions from a memory medium. Program instructions may be stored in a computer readable medium (e.g., memory). Exemplary computer-readable media include read-only memory, a random access memory, a magnetic or optical disk, or a magnetic tape.

Computational algorithms are usually optimized for metrology applications with one or more approaches being used such as design and implementation of computational hardware, parallelization, distribution of computation, load-balancing, multi-service support, dynamic load optimization, etc. Different implementations of algorithms can be done in firmware, software, FPGA, programmable optics components, etc.

A separate high-resolution system may be used for defect review. This system will generally have a higher resolution than the 2nd stage inspector. In an alternative embodiment, the 2nd stage inspector may include one or more columns that are specifically configured to achieve a higher resolution than the other scanning columns. In an electron beam column example, the system, which is either a part of the 2nd stage system or separate from the 2nd stage system, is configured to apply a lower current to the reviewing column, as compared to current applied to the 2nd stage columns' currents, so that the reviewing column achieves a relatively higher resolution than the 2nd stage columns. In other embodiments, the higher-resolution probe system and the high-resolution distributed probe system may be different types of systems, such as an AFM probe for the higher resolution system and an electron beam, or ion beam, system for the distributed probes or any combination of probes described herein.

FIGS. 1 and 2 show examples of probes arranged in linear arrays in conjunction with optical sensors. This “dual sense” technology uses the information from both optical and e-beam tools to locate defects. However, the optical tool does not resolve defects and hence can create numerous nuisance defects. In some embodiments, the e-beam tool is used to resolve and filter out the real defects from nuisance defects with a target of one wafer per hour.

In linear array systems, as described above, a single linear array can comprise 10 to 100 probes. As the number of probes in the linear array increases, the pitch of the probes decreases. For example, with a linear array of 100 probes, the probe pitch will be 3 mm in some systems. This 3 mm footprint makes it challenging to accommodate all mounting hardware and electrical connections. For example, in an SEM based system, a footprint of 3 mm makes it extremely challenging to fit all the components (Electron Source, Deflectors, Lenses and Detector(s)) into the system. As another example, in the case of an AFM, microwave near-field probes and multiple optical proximity probes result in other space constraints that must be considered. Since in a linear array system, the wafer stage must travel the full extent (300 mm) of the wafer, at least one of the axis is required to be capable of a long travel. Thus, it is more advantageous to utilize an improved configuration of probes, such as a two dimensional probe.

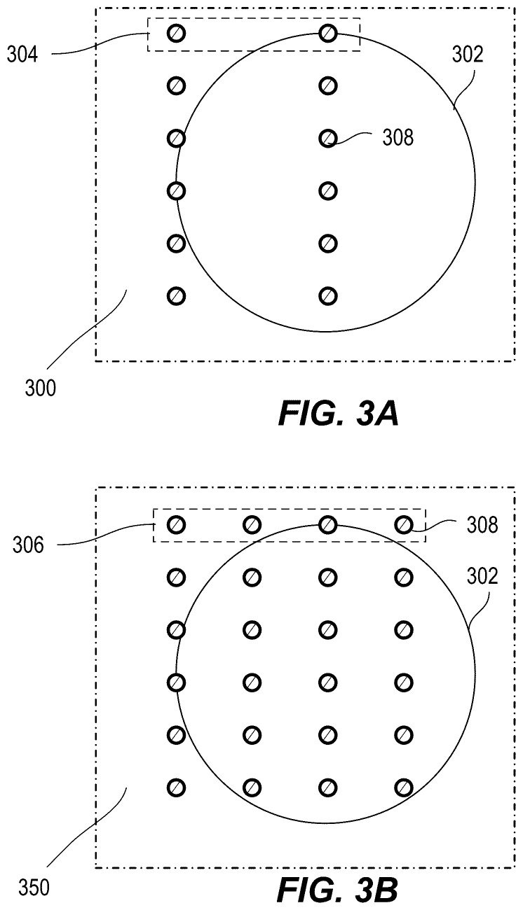

FIGS. 3A-3B illustrate a two dimensional array of high-resolution probes, in accordance with embodiments of the present disclosure. FIGS. 3A-3B introduces novel two-dimensional (2D) configurations 300 and 350. Configurations 300 and 350 each use a 2D array of probes 304 and 306 to scan wafer 302. In some embodiments, each linear array of probes is duplicated at an integral (n) divisor of wafer 302 (e.g., 300 mm/n for a 300 mm wafer). This allows for 100% wafer coverage. For example, if n=2 then the linear array spacing would be 150 mm, as shown in FIG. 3A. In addition, if n=4 the array spacing would be 75 mm, as shown in FIG. 3B, and so on. It is worth noting that the additional time in stage travel, which increases as the number of probes increases, is small (100 ms's) compared to the inspection time of one hour. The spacing may be different for other substrates. In some embodiments, different arrangements of arrays can also be used. For example, non-orthogonal arrays, hexagonally packed arrays, or other arrangement of arrays can also be used.

In some embodiments, probes 308 are miniature SEMs. In some embodiments, the column spacing can be relaxed to 50 mm pitch between columns. In some embodiments, a linear array would span the entire 300 mm in the array axis. FIG. 3A illustrates an additional 6 column array at 150 mm. The advantage of the configuration shown in FIG. 3A is that wafer 302 need only travel half the distance of the diameter of the wafer for a full wafer scan. In some embodiments, the number of columns in the array can be further divided by 2 to accommodate 4 columns in the array, as shown in FIG. 3B.

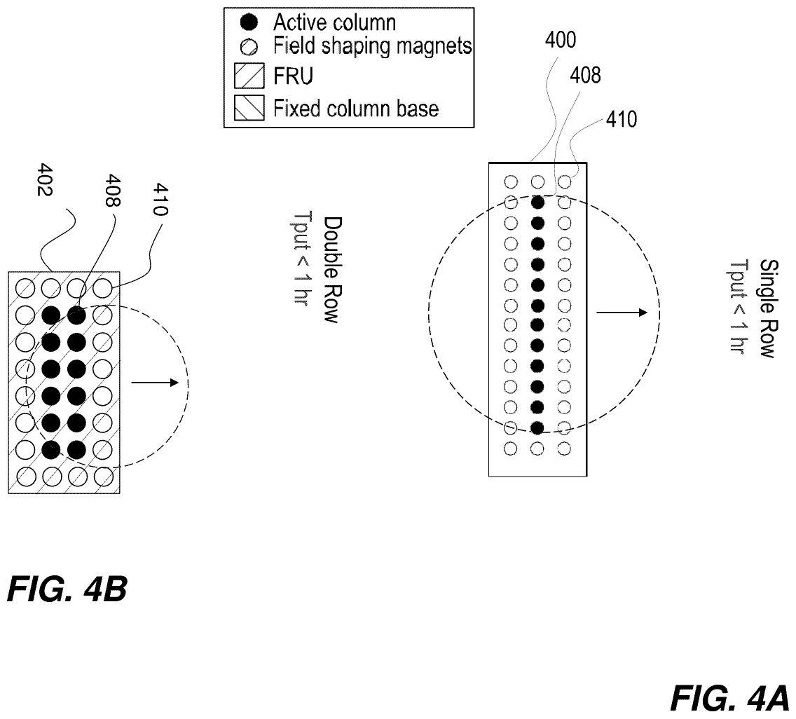

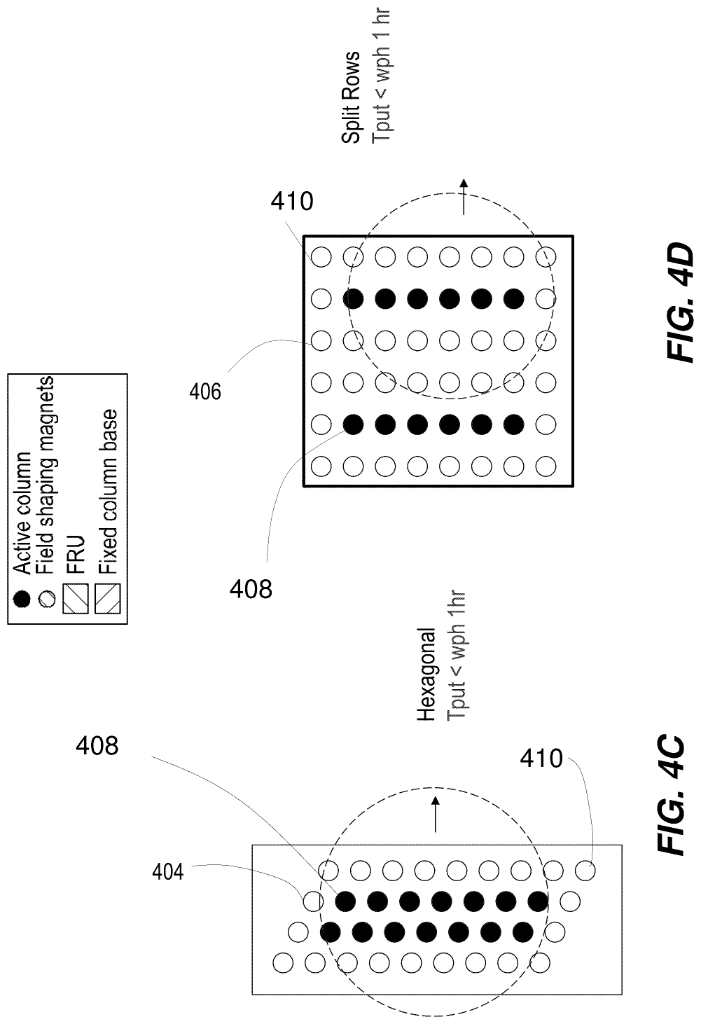

As described above, the concept of using a two dimensional array already offers advantages over the linear arrangement configuration. In addition, the manner in which probes are arranged in a two dimensional array also plays a significant role in the throughput of the system. For example, FIGS. 4A-4D illustrate different two dimensional configuration patterns, which represent several configuration options, with a different throughput for each configuration. FIG. 4A illustrates a conventional linear array. FIG. 4B illustrates a double row array. FIG. 4C illustrates a hex-shaped dual row array. FIG. 4D illustrates a split rows dual array. For each example configuration, real world assumptions were made for each of column footprint with field shaping lens, stage speed, scan size and overheads.

Referring back to FIGS. 4A-4D, each of the example configurations 400, 402, 404, and 406 show filled circles 408, which represent active columns, and unfilled patterned circles 410, which represent non-active columns. In some embodiments, columns 410 are magnetic elements, such as field shaping magnets, that keep the field over the wafer uniform. As shown in FIGS. 4A-4D, columns and probes can be arranged in multiple ways. In some embodiments, an array can be configured to be a tilted array, a square array, and even an array in the shape of a bicycle wheel that rotates (with the wafer rotating underneath the array). These different architectures have various advantages but rely on the fact that there is a very small spacing between columns.

The improvement of using a two dimensional array as described herein is the ability to occupy a very small footprint using MEMS based miniature columns. With a linear array, the spacing eventually makes it impossible to build using more probes.

As shown in FIGS. 4A-4D, the configurations all include non-active columns 410. In some embodiments, these columns are just field shaping magnets. According to various embodiments, the improvement to current technology by using these non-active columns in the configurations is the ability to minimize optical variation from the magnetic fields over the surface of that wafer. This is why simply rearranging a linear array of probes into a square array is non-obvious. In order to make the two dimensional arrays work, a combination of active and non-active columns must be arranged in a very specific and particular pattern/arrangement such that a uniform field over the surface of the wafer is achieved. In some embodiments, each active column is located adjacent to a magnetic element to minimize optical variation resulting from one or more magnetic fields. In FIG. 4A, a line of active columns are surrounded by adjacent magnetic elements. In FIG. 4B, a double row of active columns are surrounded by adjacent magnetic elements on one side of each of the active columns. In FIG. 4C, a hexagonal double row of active columns are surrounded by a hexagonal border of adjacent magnetic elements on one side of each of the active columns. In FIG. 4D, split rows are surrounded by adjacent magnetic elements.

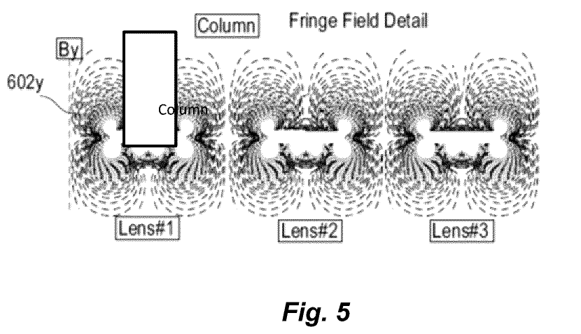

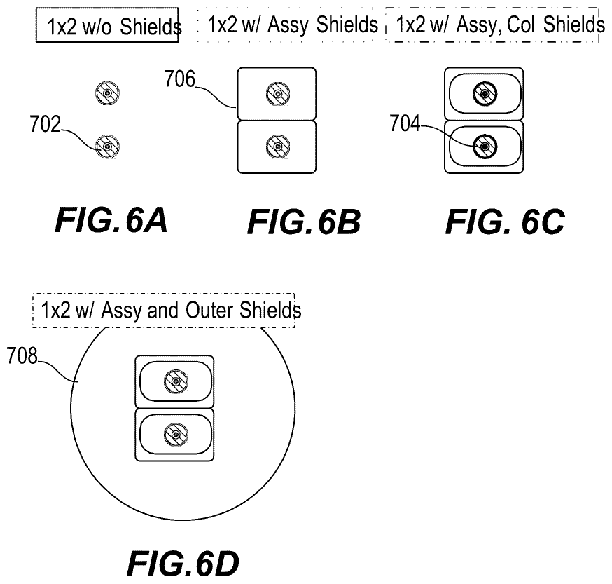

FIG. 5 shows examples of fields surrounding lenses in a particular arrangement. In addition to specific placement/arrangement patterns to increase field uniformity, some embodiments include shielding mechanisms, which are further described in FIGS. 6A-6G. In such embodiments, shielding also controls the fringe fields in the column/column array.

In some embodiments, another factor to consider is placement accuracy. As shown in the figures, each square surrounding active column 408 includes a square box surrounding the filled circle. The square box represents the spacing of the column. There is a placement accuracy associated when configuring the column. The consideration is how accurate the placement of the column's center is relative to the neighboring columns. Because of placement errors in those columns, there are restrictions on how arrays can be laid out. For example, in the tilted configuration 404, placement errors result in severe limitations on the pitch and placement of the columns.

According to various embodiments, all three factors of balancing, size of the column (achieved by using miniature columns), placement accuracy of the columns, and magnetic field uniformity have to be balanced correctly to increase the throughput by adding more columns. Simply adding more columns without more consideration may quickly tip the scales too much toward one factor, which is undesirable. However, the question of how to find the right balance to maximize the throughput is an optimization problem. Such problem can be solved using modeling. One specific method of modeling is the Monte Carlo method, which can lead to the empirical discovery of an optimal two dimensional configuration. Since, as described above, one factor that affects throughput is the uniformity of field factor, much of the modeling depends on the understanding of how the magnetic fields are affected by the placements of the active columns in relation to the placement of the non-active columns, which impacts the uniformity of the field. Configuration 406 includes two rows of active columns 408, each row being completely surrounded by non-active columns 410. Thus, in configuration 406, a single row of active columns is not lined up directly next to another single row active column. Instead, two rows of non-active columns separate the two rows of active columns from each other.

The modeling indicates putting the magnets as close as possible to get the most uniform field. However, MEMS fabrication says make the footprint as big as possible because the components are easier to fabricate, and less likely to breakdown. Another consideration is mechanical in nature. For example, kinematic mount are held to 10 microns. Any more than that leads to leads to impracticality during assembly of a mechanical fixture. An improved design takes into account all the different factors.

It was already established that throughput cannot be more than 1 hour. By comparing the values in each row, the solution to the optimization problem becomes clear.

As for the design rules, each model has to have an array size target M×N=total columns. The arrangement allows determination of the overall system throughput (after taking into account related subsystem performance). In addition, field engineering is performed by the addition of redundant magnetic lens or field shaping elements. In some embodiments, field engineering in this context refers to targeting a specific axial field strength (Bz component) and uniformity (% variation) across all columns. Further, minimizing fringing field effect, also known as transverse fields (Bx, By components), is also targeted, as fringing fields have the unwanted effect of deflecting the electron beam in a column. These unwanted deflections cause increased aberrations in the system and lower performance. In the simplest form, the field engineering comprises the addition of 1 row of dummy (inactive) magnetic lenses identical to a magnetic lens in use by a column. In a more complex form, this can involve the addition of multiple rows of dummy lenses 1+ or equivalent magnetic elements that are not the same shape or form as the original magnetic lens. In some embodiments, magnetic shielding is also considered, as well as the spacing between magnetic lenses or magnetic elements. Last, field engineering in this context includes allowances for material variation, processing, and environmental, which are also factored into the design.

The examples above illustrate the advantages and improvements of the techniques and mechanisms of the present disclosure over current linear array technology. By incorporating more probes into a 2D array, throughput is increased without putting unachievable constraints on the columns regarding size and spacing. For pitch (distance from the center of one column to the center of another column), the average constraint is 10 mm. However, in rare cases, the pitch constraint can be 3 mm. In addition, by using 2D array, strategic placement of active and non-active columns must be utilized in order to account for the B field (the more uniform the better), because each column has a focusing lens, and each lens needs a field shaping lens, which needs to be in a specific position that is related to the pitch or location or the columns. In some embodiments, the techniques and mechanisms of the present disclosure can be extended to AFM probes, near field optics, and optics probe.

As mentioned above, fringe field effects may be quite a problem during configuration design. FIG. 5 illustrates fringe field effects in array designs. A fringe field is the peripheral transverse magnetic field (Bx or By components) that create unwanted effects on the electron beam. A fringing field is larger at the edge of array 600 than in the middle (not shown). A fringe field is a transverse field effect introduced by breaking of the magnet array symmetry. It can impact static alignment voltages and aberrations. As shown in FIG. 5, fringe field lines 602 are shown surrounding lenses 604.

In some embodiments, one solution to the problem of fringe fields is to incorporate magnetic shields into the architecture. This is because placement of the active lenses are constrained due to a dependence on the uniformity around relative distances of the active lenses to the dummy lenses, which indicate locations of magnetic lanes. In addition to the position dependency, there is also a shielding dependency. If a shield is configured correctly, the configuration may be able to mitigate some of the positional dependency of the active and dummy lenses, or even eliminate the need for dummy lenses altogether.

FIGS. 6A-6D illustrate different configurations of different types of shielding. FIG. 6A illustrates a 1×2 array without any shields. As shown, lens 702 has softer lines to illustrate no shielding. FIG. 6B illustrates lens 702 being surrounded by assay shields 706. FIG. 6C illustrates lens 704, which is lens 702 plus a column shield, surrounded by assay shields. FIG. 6D illustrates the configuration in FIG. 6B with an additional outer shield 708. Through measurements and experimentation, the results for reducing fringe fields included a combination of array placement and shields.

As described above, different configurations of the two dimensional array of probes utilize magnetic-electrostatic columns. This can be accomplished with the use of magnetostatics, as described in U.S. patent application Ser. No. 17/658,637, which is incorporated by reference herein in its entirety. Using magnetostatics allows the use of fixed magnets that basically shape magnetic fields to get high resolution. One advantage of using magnetostatics is the ability to build a miniature column using silicon MEMS technology, or any “miniature” technology, in combination with a small compact magnetostatic element to get a very compact yet high resolution system.

According to various embodiments, techniques and mechanisms of the present disclosure describe the use of miniature silicon-based electron optic elements in combination with magnetostatic (permanent magnet) lenses to produce very high-performance miniature electron or ion beam columns. This combination provides high-accuracy formation and alignment of critical optical elements and the magnetic lenses provide low-aberration focusing or condensing elements. According to various embodiments, accurate assembly of the silicon and magnetic components is achievable via the multilayered assembly techniques) and is critical to achieving the highest performance (e.g., spot-size, beam current and field-of-view—FOV).

One of the biggest hurdles in incorporating magnetostatics into silicon MEMS technology has been alignment in the fabrication. Another very large hurdle is the creation of stray fields. Conventionally, electrostatic columns have been made using conventional machining technology. However, conventional machining technology cannot produce the accuracy needed for miniature electron columns. Conventional machining technology can only fabricate on the order of microns at best. However, miniature electron beam columns require accuracy on the order of nanometers.

According to various embodiments, alignment accuracy is key to the assembly process. During fabrication, the placement of patterns is all done lithographically. For example, the apertures are placed lithographically with a great deal of accuracy both in geometry and location. In some embodiments, the components have fiducials that are also lithographically placed, which allow precision in lens-to-lens placement. This is because aligning fiducial to fiducial is much more accurate than trying to capture oddly sized shapes or circles.

Thus, the techniques and mechanisms of the present disclosure provide for a design of a miniature silicon column with electron optics performance compatible with a permanent magnet. According to various embodiments, this entails a) designing bore diameters, spacings and silicon thicknesses that are compatible with standard micromachining (MEMS-micro-electro-mechanical systems) techniques and IC technologies, and are not in violation of commonly accepted high-field practices, b) incorporating sufficient fiducials throughout the components (including the magnet) to ensure accurate alignment between elements, c) designing magnet size, performance and structure to ensure highest performance (including possibly bias magnet for E×B fields) and d) understanding the tolerance requirements for each individual element. In some embodiments, an assembly technique whereby each component is accurately aligned within the column within specifications detailed above is utilized. In some embodiments, the tools required for column assembly require accurate calibration.

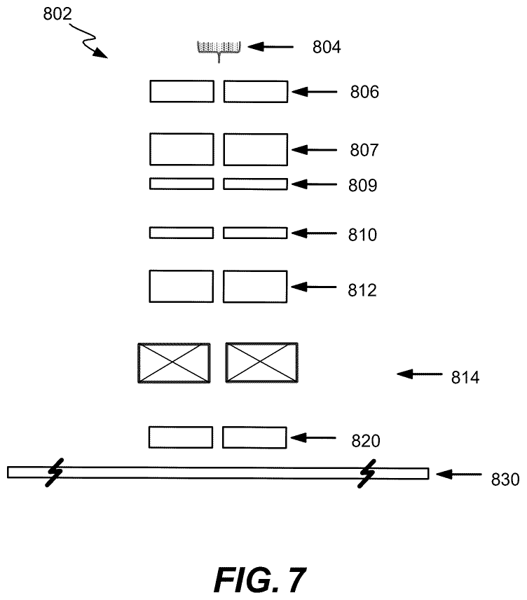

FIG. 7 illustrates an example electron beam column, in accordance with embodiments of the present disclosure. FIG. 7 illustrates an example miniature electron beam column 800, in accordance with embodiments of the present disclosure.

In some embodiments, an electron beam is emitted from electron source 804. In some embodiments, source 804 is a thermal field emitter or a Schottky source. In some embodiments, extractor/condenser 806 extracts electrons from source 804. In some embodiments, the extractor portion (the first half of extractor/condenser 806) is an anode that has a high voltage applied to it, thereby creating an electric field, in order to extract electrons from source 804. In some embodiments, beneath the extractor portion is the condenser portion of extractor/condenser 806. In some embodiments, the condenser portion is what makes the electrons parallel down the column. Beneath extractor/condenser 806 is steering deflector/limiting aperture 809. The deflector portion effectively steers the electron beam into the limiting aperture portion. In some embodiments, limiting aperture portion defines the accepted angle at the source. In some embodiments, the limiting aperture portion defines the numerical aperture (NA), which then determines the resolution and the beam current of the system. In some embodiments, the limiting aperture portion filters the beam down to the order of tens of microns.

In some embodiments, the electron beam then passes through the through-hole of detector 810. In some embodiments, detector 810 is face down toward the sample 830. In some embodiments, detector 810 is a silicon diode, such as a PIN diode. In some embodiments, the electron beam then passes through dual scanning deflectors 812. In some embodiments, dual scanning deflectors 812 are scan coils raster scan the electron beam over sample 830. In some embodiments, magnetic objective lens 814 then focuses the electron beam onto sample 830. In some embodiments, magnetostatic lens 814 includes a high mu metal configured to direct magnetic fields to form a focusing field that further focuses the electron beam. In some embodiments, magnetostatic lens 814 is designed to better align e-beam column 800 and to increase performance.

It should be noted that because of the state of the current art, it is very difficult to insert a magnetostatic lens into an electron beam column. Normally, a magnetostatic lens would wreak havoc on the function of the electron beam column due to the fields emanating from the magnet, which interact with the electron fields in the upper part of the column. By way of example, measured or modeled lateral fields on the backside of the magnetostatic lens can approach 3-5 Gauss, depending on the distance from the optical axis. For reference, the earth's magnetic field is ˜0.5 Gauss. Under these conditions, using the well-known equation of motion for an electron in a constant magnetic field, r=mv/qB (where r=radius of curvature, m=mass electron, v=electron velocity, q=charge on the electron and B=magnetic field), the expected deflection of an 8 keV electron is 7 μm per mm of travel through the column. If apertures in the column are roughly 80 μm in diameter, the electrons will be blocked if they travel more that 2 mm. In addition, this additional field problem can normally be addressed using an electromagnetic lens. However, electromagnetic lenses require too much power and are too large for miniature electron beam columns.

In some embodiments, these challenges can be addressed by first arranging multiple columns into an array and then subsequently adding shields. In some embodiments, the shield is also made of a mu metal. In some embodiments, each electron beam column is fitted with two mu metal field termination shields near the electron source. In some embodiments, additional shields are placed in the electron column system to short circuit the additional magnetic field and have return paths for the magnetic fields such that those magnetic fields do not interfere with the electron beam of the column which comes through the middle of the column. In such embodiments, without additional shields, the magnetic fields generated by the magnetostatic lens are going to leak up into the electron beam path and if the beam tries to come through the column, it either gets distorted or it gets deflected and will not go through the column correctly. In some embodiments, the column is built with layers of mu-metal placed horizontally (or perpendicular to the beam). In some other embodiments, there may be multiple layers of shielding e.g. shield-in-shield to improve the attenuation of stray fields

In some embodiments, a column comprises lens stacks (lenses), a permanent magnet (magnet), and multilayer boards (boards). In some embodiments, the lens stack are micro-machined multi-layer structures consisting of silicon apertures and glass isolators. In some embodiments, the multilayer boards consist of ceramic multilayers, a metal support structure, and connectors. In some embodiments, each lens and magnet include lithographically placed fiducials designed to mate with vertically adjacent lenses. In some embodiments, assembly of the lenses and magnet onto the boards is done using a high placement accuracy pick and place assembly tool.

According to various embodiments, the performance of the columns depends, in part, on placing the center of each lens and magnet precisely on the optical axis. In some embodiments, using a coordinate system where the x and y axes form a Cartesian plane, the optical axis is perpendicular to the x-y plane. In some embodiments, the location of optical axis is defined by location of the center of the first lens.

According to various embodiments, the column is designed such that each lens is aligned to the lens directly below it. In such embodiments, the placement of the center of each lens relative to the optical axis is determined by the placement of the lithographically placed fiducials and the accuracy of the pick and place tool. In many cases, lens-to-lens alignment is the most precise method of minimizing total stack up misalignment of the lens assembly.

In some embodiments, each lens must be aligned linearly and rotationally to printed contact pads on the board. In such embodiments, because lenses are aligned to lenses, not to the board, and the optical axis is determined by the placement of the first lens, the board-to board alignment must be controlled. In some embodiments, this is done using a pin and slot alignment.

In some embodiments, a single electron column utilizes an array of lenses. In other embodiments, a single electron column utilizes a single magnetostatic lens. With only a single lens, the bore diameter of the lens can be much larger. With a larger magnetic lens bore, this allows for backscattered electrons to be collected at the detector.

In some embodiments, objective lens 814 is actually round in shape. In such embodiments, the round shape, as opposed to the traditional square shape, allows the lens to be turned on a lathe, thereby improving the precision and accuracy of the fabrication of the lens. Higher precision means the fields themselves end up being more precise and allow a higher resolution, while introducing fewer aberrations. The better geometry of the magnet allows placement with more precision.

In some embodiments, after the electron beam is raster scanned over sample 830, the electrons are reflected back as secondary/backscattered electrons toward detector 810 in a diffuse manner. In some embodiments, dual deflector 812 is responsible for steering the beam off to the side.

As shown in FIG. 7, in some embodiments, miniature electron beam column 802 includes a post-lens element 820 in order to control the SE and BSE signal on detector 810. In some embodiments, post-lens element 820 is a post-lens deflector/dynamic focus element. In some embodiments, having the deflector be post lens reduces introduction of additional aberrations or distortions from the lens itself. In addition, in some embodiments, post-lens element 820 can also perform dynamic focus to always ensure that the beam is in focus. Also shown in FIG. 7, in some embodiments, electron beam column 802 replaces steering deflector/limiting aperture 808 into a separate dual steering deflector 807 and a separate limiting aperture 809. In such embodiments, a separate dual steering deflector 807 gives the column improved ability to steer the beam back on its axis, thereby improving resolution, as described in U.S. patent application Ser. No. 17/862,052, which is incorporated by reference in its entirety.

Certain embodiments of the present disclosure presented here generally address the field of electron beam columns, and are not limited to the hardware, algorithm/software implementations and architectures, and use cases summarized above.

Although the foregoing disclosure has been described in some detail for purposes of clarity of understanding, it will be apparent that certain changes and modifications may be practiced within the scope of the appended claims. It should be noted that there are many alternative ways of implementing the processes, systems, and apparatus of the present disclosure. Accordingly, the present embodiments are to be considered as illustrative and not restrictive, and the disclosure is not to be limited to the details given herein.

Although the foregoing disclosure has been described in some detail for purposes of clarity of understanding, it will be apparent that certain changes and modifications may be practiced within the scope of the appended claims. It should be noted that there are many alternative ways of implementing the processes, systems, and apparatus of the present disclosure. Accordingly, the present embodiments are to be considered as illustrative and not restrictive, and the disclosure is not to be limited to the details given herein.

What is claimed is:

1. A device comprising:
a two dimensional array of electron beam columns configured to inspect a wafer, the two dimensional array including at least one electron beam column or a magnetic element located in each dimension of the two dimensional array,
wherein each electron beam column includes:
an electron source, and
a detector in line with the electron source,
wherein the two dimensional array is arranged such that each electron beam column is located adjacent to a magnetic element to minimize optical variation resulting from one or more magnetic fields.

2. The device of claim 1, wherein the device comprises silicon lenses and lens stack fabricated wafer-scale using MEMS and IC technologies.

3. The device of claim 1, wherein each electron beam column includes a magnetic objective lens in line with the electron source and the detector.

4. The device of claim 1, wherein the two dimensional array includes at least one row of electron beam columns completely surrounded by adjacently placed magnetic elements to increase throughput or make the one or more magnetic fields uniform across the two dimensional array.

5. The device of claim 1, wherein the two dimensional array includes two rows of electron beam columns adjacent to one another and magnetic elements completely surrounding the two rows of electron beam columns.

6. The device of claim 1, wherein the two dimensional array is arranged such that two hexagonally shaped rows of electron beam columns are completely surrounded by magnetic elements.

7. The device of claim 1, wherein the two dimensional array includes shielding elements surrounding each electron beam column in the two dimensional array in order to reduce fringe field effects.

8. A system comprising
a wafer;
a controller; and
a two dimensional array of electron beam columns configured to inspect the wafer, the two dimensional array including at least one electron beam column or a magnetic element located in each dimension of the two dimensional array,
wherein each electron beam column includes:
an electron source, and
a detector in line with the electron source,
wherein the two dimensional array is arranged such that each electron beam column is located adjacent to a magnetic element to minimize optical variation resulting from one or more magnetic fields.

9. The system of claim 8, wherein the system comprises silicon lenses and lens stack fabricated wafer-scale using MEMS and IC technologies.

10. The system of claim 8, wherein each electron beam column includes a magnetic objective lens in line with the electron source and the detector.

11. The system of claim 8, wherein the two dimensional array includes at least one row of electron beam columns completely surrounded by rows of adjacently placed magnetic elements to increase throughput or make the one or more magnetic fields uniform across the two dimensional array.

12. The system of claim 8, wherein the two dimensional array includes two rows of electron beam columns directly adjacent to one another and magnetic elements completely surrounding the two rows of electron beam columns.

13. The system of claim 8, wherein the two dimensional array is arranged such that two hexagonally shaped rows of electron beam columns are completely surrounded by magnetic elements.

14. The system of claim 8, wherein the two dimensional array includes shielding elements surrounding each electron beam column in the two dimensional array in order to reduce fringe field effects.

15. A device comprising:
a two dimensional array of electron beam columns configured to inspect a wafer, the two dimensional array including at least one electron beam column or a magnetic element located in each dimension of the two dimensional array,
wherein each electron beam column includes:
an electron source, and
a detector in line with the electron source,
wherein the two dimensional array is arranged such that each electron beam column is located adjacent to a magnetic element to minimize optical variation resulting from one or more magnetic fields.

16. The device of claim 15, wherein the device comprises silicon lenses and lens stack fabricated wafer-scale using MEMS and IC technologies.

17. The device of claim 15, wherein each ion beam column includes a magnetic objective lens in line with the electron source and the detector.

18. The device of claim 15, wherein the two dimensional array includes at least one row of electron beam columns completely surrounded by rows of adjacently placed magnetic elements to increase throughput or make the one or more magnetic fields uniform across the two dimensional array.

19. The device of claim 15, wherein the two dimensional array includes two rows of electron beam columns directly adjacent to one another and magnetic elements completely surrounding the two rows of electron beam columns.

20. The device of claim 15, wherein the two dimensional array is arranged such that two hexagonally shaped rows of electron beam columns are completely surrounded by magnetic elements.
